(19) United States
(12) Patent Application Publication
(10) Pub. No.: US 2014/0000684 A1
(43) Pub. Date: Jan. 2, 2014

(54) METHOD FOR FORMING AN ELECTRICAL INTERCONNECTION IN AN ORGANIC PHOTOVOLTAIC DEVICE AND AN ORGANIC PHOTOVOLTAIC DEVICE MADE BY THE SAME

(71) Applicant: Jan Blochwitz-Nimoth, Dresden (DE)

(72) Inventor: Jan Blochwitz-Nimoth, Dresden (DE)

(21) Appl. No.: 13/990,102

(22) PCT Filed: Dec. 5, 2011
(86) PCT No.: PCT/EP2011/006078

§ 371 Date: Aug. 16, 2013

(30) Foreign Application Priority Data
Dec. 3, 2010 (EP) 10193587.2

(51) Int. Cl. H01L 31/05

(52) U.S. Cl. CPC H01L 31/0504
USPC 136/251; 438/64

(57) ABSTRACT

The present invention concerns a method for forming an electrical interconnection in an organic photovoltaic device, the method comprising steps of providing a first conductive layer (31), providing an organic photovoltaic layer (32), over the first conductive layer, providing a second conductive layer (33), over the organic photovoltaic layer, and providing an electrical interconnection between the first conductive layer and the second conductive layer.

The invention relates to a method for forming an electrical interconnection in an organic photovoltaic device and an organic photovoltaic device.

### BACKGROUND OF INVENTION

Organic photovoltaics (OPV) offer a big promise for the efficient and large scale conversion of light into electricity. The production of organic photovoltaic devices is less material demanding than the production of inorganic crystalline photovoltaic devices. The production also consumes considerably less energy than the production of any other inorganic photovoltaic device.

Efficiency of organic photovoltaic devices has been improving steadily. In 2008 a certified power conversion efficiency value of 5% was reached, and in 2010 the psychological barrier of 8% was broken, aligning the efficiency of the organic photovoltaic devices to typical values of amorphous Si devices.

OPV devices comprise at least one solar cell, or an arrangement of solar cells. Organic solar cells have the most different layer stack architectures. Typically they comprise at least one organic photovoltaic layer between two electrodes. That organic layer can be a blend of a donor and an acceptor such as P3HT (poly3-hexyl-tiophene) and PCBM (phenyl C61 Butyric Acid Methyl Ester). Such simple device structures only achieve reasonably efficiencies if interfacial injection layers are used to facilitate charge carrier injection/extraction (Liao et al., Appl. Phys. Lett., 2008. 92: p. 173303). Other organic solar cells have multi-layer structures, sometimes even hybrid polymer and small molecule structures. Also tandem or multi-unit stacks are known (U.S. Pat. No. 7,675,057, or Ameri, et al., Energy & Env. Science, 2009. 2: p. 347). Multi-layer devices can be easier optimized since different layers can comprise different materials which are suitable for different functions. Typical functional layers are transport layers, optically active layers, injection layers, etc.

Optically active materials are materials with a high absorption coefficient, for at least a certain wavelength range of the solar spectra, which materials convert absorbed photons into excitons which excitons in turn contribute to the photocurrent. The optically active materials are typically used in a donor-acceptor heterojunction, where at least one of the donor or acceptor is the light absorbing material. The interface of the donor-acceptor heterojunction is responsible for separating the generated excitons into charge carriers. The heterojunction can be a bulk-heterojunction (a blend), or a flat (also called planar) heterojunction, additional layers can also be provided (Hong et al, J. Appl. Phys., 2009. 106: p. 064511).

The loss by recombination must be minimized for high efficiency OPV devices. Therefore, the materials in the heterojunction must have high charge carrier mobilities and high exciton diffusion lengths. The excitons have to be separated at the heterointerface and the charge carriers have to leave the optically active region before any recombination takes place. Currently, fullerenes (C60, C70, PCBM, and so on) are the preferred choice as acceptor in OPV devices.

Transport materials for transport layers for opto-electronic devices are required to be transparent, at least in the wavelengths wherein the device is active, and have good semiconducting properties. These semiconducting properties are intrinsic, such as energy levels or mobility, or extrinsic such as charge carrier density. The charge carrier density can also be influenced, for instance, by doping the material with an electrical dopant.

Although the current efficiency record for an organic solar cell is about 8%, this value is still much lower than the theoretical Shockley-Queisser limit applied to multiple tandem solar cells of 86%. For further increasing the efficiency, all loss mechanism has to be taken into account, such as optical optimizations, optimization of excitonic transport and separation, electrical optimizations, etc. Still, when transferring a single solar cell into larger arrangements (called herein as OPV device), other losses occur due to increased series resistance. The series resistance is mainly due to the thin film electrodes used in a organic solar cell, very often due to the resistance of the transparent electrode, since the non-transparent one can be made thicker and hence more conductive. Organic solar cells with higher efficiency have lower currents and higher voltages, to reduce the effect of the series resistance. Such higher voltages are obtained by using multiple tandem solar cells as explained in U.S. Pat. No. 7,675,057.

To realize a large area OPV device, usually individual solar cells are connected in series. The series connection has a drawback: the area, of the surface which is exposed to light, is reduced. That area is necessary to provide the interconnection between top and bottom electrodes from adjacent devices. Such interconnections require several patterning steps.

The known patterning processes are complex and time demanding. Typically, shadow masks are used to define the evaporation pattern of the several layers. The alignment accuracy of the shadow mask defines the useful and clearly visible gap, between the organic solar cells. Alternatively, if no fine masking is available, the gap between the organic solar cells will be very large (in the range of 1 mm and above).

### SUMMARY OF THE INVENTION

The invention solves the problem of the prior art, providing an OPV device with series connected solar cells, having a reduced gap necessary for the connections. The invention also provides a method for producing such an OPV device, which method doe not required the use of shadow masks for creating the series interconnection.

The invention provides a method for forming an electrical interconnection in an organic photovoltaic device, the method comprising steps of:
providing a first conductive layer on a substrate,
providing an organic photovoltaic layer, over the first conductive layer,
providing a second conductive layer, over the organic photovoltaic layer, and
providing an electrical interconnection between the first conductive layer with the second conductive layer.

The step of providing the interconnection is performed preferably by laser and after the steps of providing a second conductive layer.

In a preferred embodiment, step of providing the interconnection comprises providing several aligned interconnections. The aligned interconnections are electrical interconnections made consecutively in a line which can be a straight line or a curve, the interconnections can be merged or spaced apart from each other. The aligned interconnections can consist of several spot sized interconnections aligned in a straight or curved line.

Optionally the aligned interconnections are more than one line in parallel such as double or triple aligned interconnections.

In an advanced mode of the invention, the interconnecting step is preceded by the step of encapsulating the organic photovoltaic device. The laser light may be irradiated through the substrate or through the encapsulation, however it is preferred that the laser which does the electrical interconnection is irradiated through the encapsulation. In some cases, UV filters, or other layers (films) are fabricate over the encapsulation. It is preferably that the deposition of these layers is made after the electrical interconnection. The encapsulation may be a glass cover or thin film encapsulation. It is necessary that the encapsulation does not absorb the laser light (Absorbance<2%). A highly transparent encapsulation, with a transmittance>95% to the wavelength of laser being used is preferred. The electrical interconnection is made by a laser process, in which step vacuum or inert atmosphere are not required.

At least one of the organic photovoltaic layer or the second conductive layer, and preferably both layers, are formed on the substrate by a maskless deposition process comprising a step of maskless depositing materials in at least an active area.

In a preferred embodiment, for a method of producing an OPV device comprising a plurality of organic solar cells, the method includes providing a substrate, and providing a first conductive layer over the substrate. The first conductive layer is patterned by any known method. Preferentially the step of providing a first conductive layer includes:
depositing a first conductive layer over a substrate;
patterning the first conductive layer by laser.

In the patterning the first conductive layer step, parts of the first conductive layer are removed, forming at least two electrically isolated areas spaced by narrow gaps, a first and a second section. This step is preferentially performed with laser ablation to ensure that the gaps are very narrow.

Known lasers can be used for the sectioning step, which is applied on the first or the second conductive layer (or on both). For instance, a table top lasers from ACI Laser-components.

Preferentially, the step of patterning the first conductive layer by laser is performed before the step of providing an organic photovoltaic layer. This can easily be done since this step could be performed outside of the process equipment for the remaining layer (specially the photovoltaic layers) and careful cleaning of the patterned first conductive layer is still provided to remove remaining particles from the laser ablation step.

In an advanced mode of the invention, in the method for forming an electrical interconnection in an organic photovoltaic device, the step of providing an interconnection, includes the steps of:
provide an electrical interconnection between the first section of the first conductive layer and the second section of the second conductive layer; and
section the second conductive layer into a first section and a second section, wherein the first section of the second conductive layer is electrically short disconnected to the first section of the first conductive layer and is electrically short connected to the second section of the first conductive layer.

Forming the interconnection with laser requires that the laser does not ablate the layers; therefore it is preferably that the laser power is lower than the power used for ablation. It is further preferably that the power of the laser is between 200 mW to 15 W, more preferably between 200 mW to 5 W, for an infrared laser with a wavelength between 800 to 10 μm; for laser with shorter wavelengths in the range of 300 to 800 nm, it is preferred that the power is between 200 mW and 3 W, more preferably from 200 mW to 1 W, even more preferably from 200 to 500 mW.

The laser emission can be between 300 and 550 nm, especially in the range between 300 and 450 nm; in these ranges, the absorption of the metal layer is stronger, and it is easier to promote a heating. Any laser can be used, such as tripled or quadrupled Nd lasers, excimer lasers, or semiconducting lasers. Non limiting examples of such short wavelength lasers are InGaN blue-violet laser, tripled Nd:YAG, XeF excimer layer.

The laser used for the electrical interconnection can also have a wavelength from 500 to 1500 μm. Exemplary lasers are Nd lasers operating in their main wavelength which is typically in the range of 1020-1050 nm, however other modes as well as the double frequency can be used. Examples of such lasers are Nd:YAG at 1064 nm or 532 nm; Nd:YVO4 at 914, 1064 or 1342 nm; Nd:YLF at 1047 or 1053 nm.

Other wavelengths and power values can also be used, a calibration step can be necessary to find the optimum configuration of the laser.

Gas and excimer lasers can also be used, as well as semiconductor or fiber lasers. The laser can also match the absorption of transparent oxide layer (if such is used as first or second conductive layer); it can also match an absorption wavelength of the organic semiconductive layer. Preferentially, pulsed lasers are used which make it easier to control the laser power per shot, which shot is forming the electrical interconnection.

For a diode-pumped Nd:YAG (1064 nm), ns Q-switched laser, good results were obtained using pulses with an energy higher or equal to 10 μJ. About 1000 shots at 10 μJ do deliver a good contact.

With a ps diode-pumped Nd:YAG (1064 nm), Q-switched laser by Pockets cell, best results were obtained at power above 300 mW. Tested repetition rates were between 10 kHz and 640 kHz.

In an advanced alternative mode of the invention, in the method for forming an electrical interconnection in an organic photovoltaic device, the step of providing an interconnection, includes the steps of:
section the second conductive layer into a first section and a second section; and
electrically interconnect the first section of the first conductive layer with the second section of the second conductive layer, after sectioning the second conductive layer.

Preferentially, the step of providing the electrical interconnection is made after the step of providing the encapsulation, or at least part of the encapsulation.

The invention also foresees an OPV device made by the method as described above, the device comprising a substrate, a first conductive layer, a second conductive layer, a first string, the first string comprising in-series connected organic solar cells over the substrate (see for example FIG. 4), wherein the series connection comprises electrical interconnections between the first conductive layer of a first solar cell and the second conductive layer of a second solar cell, wherein the interconnection is made by laser.

The electrical interconnection is formed by a laser process, namely the irradiation of light into a connection area in which the interconnection is to be formed. The material modification generated by the laser process laser may be, for example, a molten material, a re-solidified material, or other. The interconnection can be recognized by its typical shape formed by the high energy density of the laser. Preferentially, the interconnection is a punctual connection (dot like). In a large area device, the interconnections need to provided enough conductivity to transport larger current densities, therefore, the interconnections are a plurality, preferentially a plurality of dots, which dots may be spaced apart from each other or merged to each other. Optionally, the device comprises multiple strings. A calibration step can be introduced to calibrate the laser parameters before performing the interconnection step.

In one embodiment of the invention, the OPV device comprising a string, further comprises electrical terminals at the string's ends.

In another embodiment of the invention, the OPV device comprising a string, further comprises a second string, which first string and second string are connected in parallel by electrical connecting their positive terminals to a common terminal, and electrical connecting their negative terminals to another common terminal. This embodiment also foresees multiple strings connected in parallel, wherein each string is a string of organic solar cells connected in series.

Preferably the OPV device in all embodiments is a very large area device. The area of the device is preferentially larger than about 25 cm², preferentially larger than about 100 cm². Each individual device is preferentially larger than 1 cm².

An advantage of the invention is the realization of large area OPV devices comprising arrays of solar cells connected together, with maximum area utilization.

Another advantage is the maskless production process, which enhances production efficiency, reducing maintenance, material consumption, calibration complexity, and considerably increasing the output-speed. The invention consequently also increases the production yield.

Further the production tool complexity is reduced; in the special case of production with VTE or organic vapor phase deposition, the deposition chamber is simplified and can be limited to the deposition of continuous layers. The present invention also does not require the use of moving shadow masks during deposition of the layers.

The invention is preferably used in web production methods, such as roll-to-roll processing.

An especial feature of the invention is the use of the OPV devices, produced with the inventive method, in glass for buildings, such applications are also known as building integrated photovoltaics. Especially in windows and glass façades, were semi-transparent OPV devices can be used; OPV devices with no (or almost no) visible patterns give the optical impression of a smooth optical coating.

### SUMMARY OF THE FIGURES

In the following, the invention will be described in further detail, by the way of example, with reference to different embodiments. The figures show:

FIG. 1 a flow chart of the method for forming a device with an organic photovoltaic layer and an interconnection,

FIG. 2 a flow chart of the method of producing an OPV device comprising at least two, in series connected solar cells,

FIG. 3a a device without interconnection,

FIG. 3b the device of FIG. 3a after the sectioning of the second conductive layer is performed,

FIG. 3c the device of FIG. 3b after the interconnections are formed,

FIG. 4 a top view schematic of an OPV device comprising series connected solar cells,

FIG. 5 a top view schematic of an OPV device comprising series connected solar cells,

FIG. 6a-c demonstrates the production of an exemplary embodiments, and

FIG. 7 a schematic showing the equipment and the individual steps for the production of a photovoltaic device on a web.

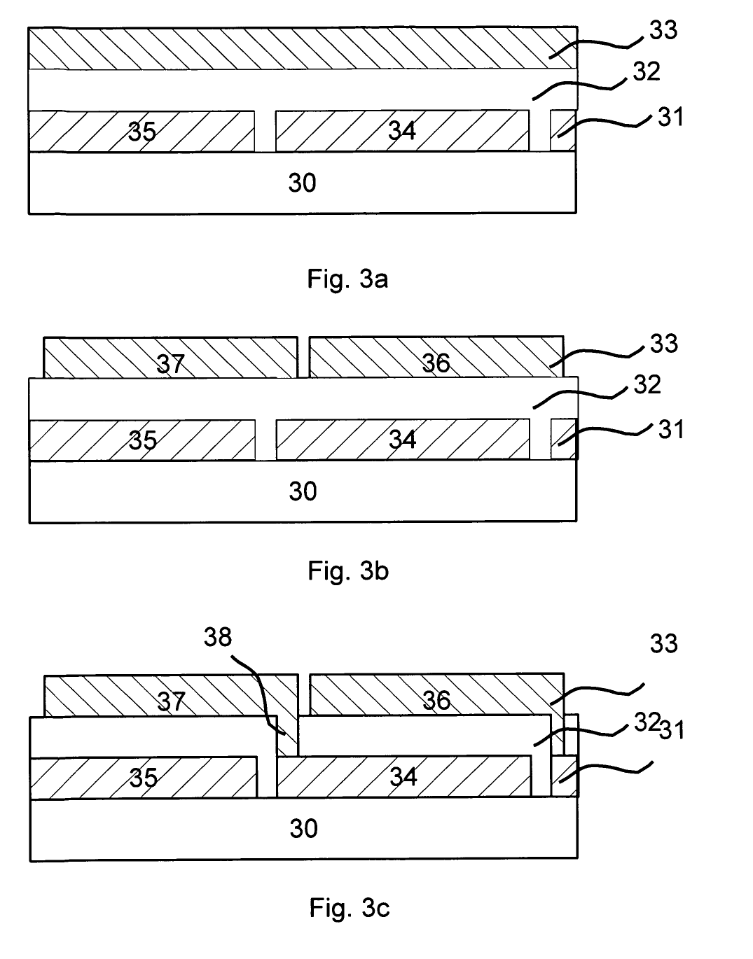

The figures are only schematic representations, and are not in scale. Especially in FIG. 3a-c, the layer thickness is not in scale, as the substrate is usually much thicker than the other layers. Also the interconnection and the borders of the layers do not form a right angle.

### Embodiments

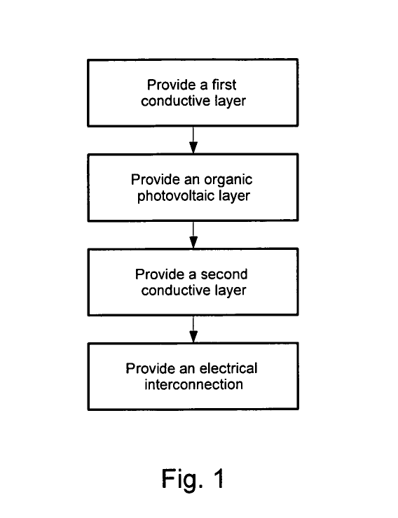

FIG. 1 shows a flow chart of the method of producing an OPV device, the method comprising the steps of providing a first conductive layer, which is provided on a substrate, providing an organic photovoltaic layer over the first conducting layer, providing a second conductive layer over the organic photovoltaic layer, and providing an electrical interconnection between the first and second conductive layers. As shown in the figure, the electrical connection is provided after the deposition of the second conductive layer.

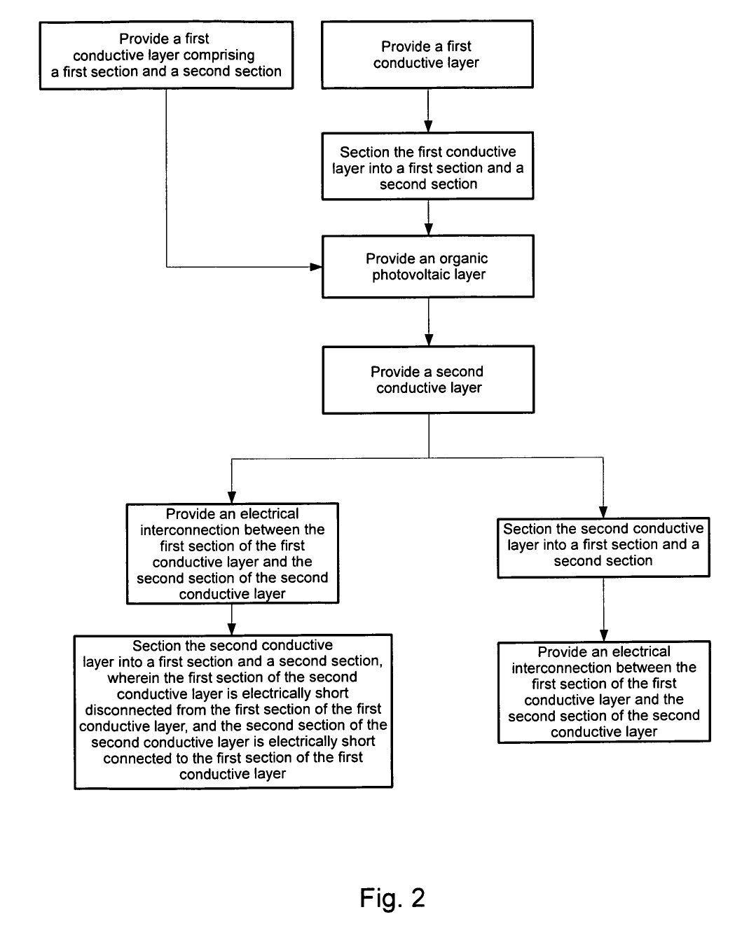

FIG. 2 shows a flow chart of the method of producing an OPV device comprising at least two, preferentially several, individual solar cells connected in series. The method comprises the step of providing a first conductive layer over a substrate, and the step of sectioning the first conductive layer patterned into at least a first and a second sections, alternatively the first conductive layer can be provided into at least a first and a second sections. The at least a first and a second sections of the first conductive layer are used to form the bottom electrodes of the solar cells, which solar cells will be connected in series. FIG. 2 shows that an organic photovoltaic layer is provided on the first conductive layer. This organic photovoltaic layer is provided in an essentially patterned way, meaning that it is a closed and continuous layer. A second conductive layer is provided over the photovoltaic layer. After the deposition of the second conductive layer, the following steps are provided to connect the individual organic solar cells in series, which steps can also be executed in reverse order: (i) the second conductive layer is sectioned into at least a first and a second section. The sections of the second conductive layer also provide the top electrodes for the organic solar cells. The section effectively separates the top electrodes of the individual solar cells from each other; (ii) An electrical interconnection is formed between the first section of the first conductive layer and the second section of the second conductive layer. The electrical interconnection electrically connects the top electrode on an organic solar cell to the bottom electrode of an adjacent solar cell providing an electrical series connection.

Still on the method of FIG. 2, the steps of sectioning the second conductive layer and the step of creating the interconnection can be made under similar conditions as used for the deposition of the photovoltaic layer, e.g. under high vacuum. However, it is preferred that these steps are made under more relaxed conditions, preferably under inert gas atmosphere, or even in atmosphere (air), under a flux of protective gas. Under such conditions, it is easier to remove possible waste materials with minimum contamination, of e.g. a vacuum chamber, and it is easier to manage the scanning laser process needed to create many interconnections.

More preferably, at least a first encapsulation, such as a passivation layer, or even the complete encapsulation, is provided before the step of creating the interconnection. This enables the interconnection to be made under relaxed conditions, for instance, in air. In air, it is easier to handle laser positioning and there is no generation of waste material outside the encapsulation.

The encapsulation can be, for example, a glass lid with an air-gap, laminated foil, edge glued foil, direct thin film encapsulation.

FIG. 3a shows a device comprising a first conductive layer 31 over a substrate 30, an organic photovoltaic layer 32, and a second conductive layer 33. The first conductive layer 31 comprises a first section 34 and a second section 35. After the step of patterning the second conductive layer into a first 36 and a second 37 sections, the device can be represented schematically by FIG. 3b. In FIG. 3B, the individual solar cells are defined by the overlapping of sections 37 and 35, and the overlapping of sections 34 and 36. The interconnection 38 is demonstrated in FIG. 3c, here the second section 37 of the second conductive layer 33 is electrically connected to the first section 34 of the first conductive layer 31. Effectively, the interconnection 38 is a low resistance electrical connection between layers 37 and 34. While the layer configuration depicted in FIG. 3a precede the steps of interconnecting (FIG. 3c) and sectioning the second conductive layer (FIG. 3b), the latest 2 can be performed in reverse order.

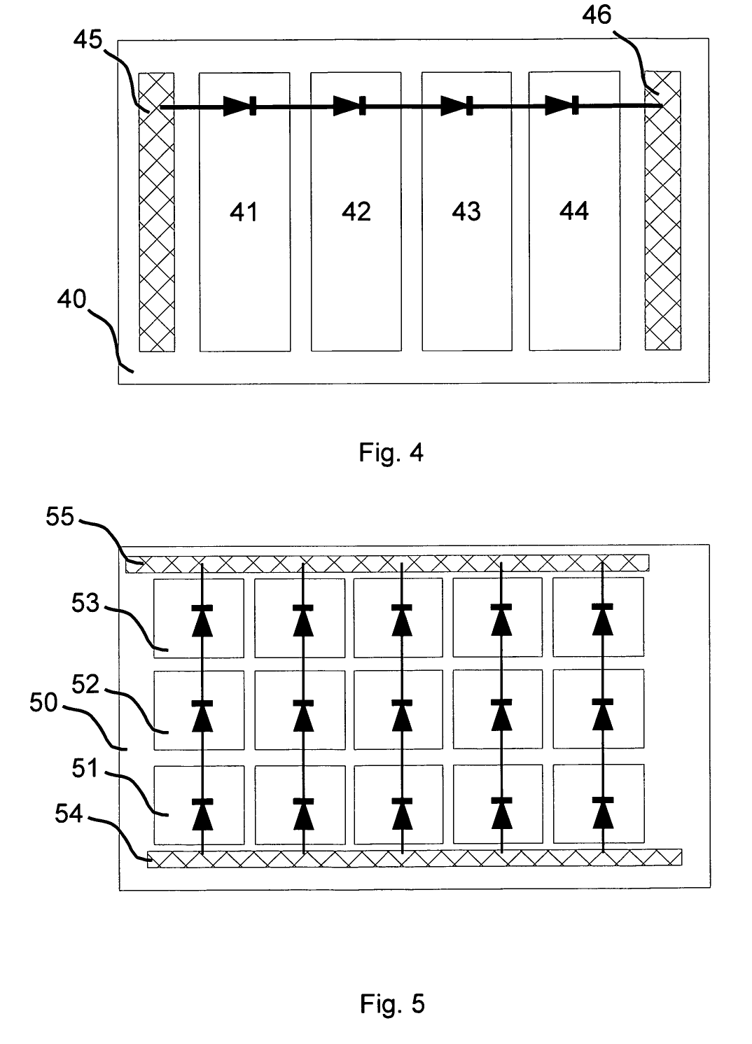

FIG. 4 shows a schematic of an OPV device comprising a substrate 40, a string of organic solar cells connected in series 41, 42, 43, 44 and two end-connections 45, 46. Symbols of diodes are overlapped to the OPV device to enhance the representation of the string of series connected organic solar cells. The individual organic solar cells are represented by their active areas 41, 42, 43, 44. The sectioning of the conductive layers and the interconnections (see FIG. 3a-c for details) are formed in the spaces between the adjacent organic solar cells (between 41 and 42, between 42 and 43, and so on). At least one of the end connections 45, 46 can comprise or be made of an extension of the first or second conductive. The schematic of FIG. 4 can be, for instance, made from a web substrate, such as a continuous sheet of paper, metal, or polymer. The orientation of the web can be parallel to the longest sides of the rectangle representing the substrate 40. Alternatively, for wide webs, the orientation of the web can be parallel to the shortest sides of the rectangle representing the substrate 40.

FIG. 5 shows an schematic of an OPV device comprising a substrate 50, a multiples strings connected in parallel, each string comprising a solar cells connected in series. A first string of organic solar cells connected in series is represented by solar cells 51, 52, 53 and two end-connections 54, 55. Symbols of diodes are overlapped to the OPV device to enhance the representation of the string of series connected organic solar cells. The individual organic solar cells are represented by their active areas 51, 52, 53. The sectioning of the conductive layers and the interconnections (see FIG. 3a-c for details) are formed in the spaces between the adjacent organic solar cells (between 51 and 52, between 52 and 53). At least one of the end connections 54, 55 can comprise or be made of an extension of the first or second conductive.

The schematic of FIG. 5 can be, for instance, made from a web substrate, such as a continuous sheet of paper, metal, or polymer. The orientation of the web can be parallel to the longest sides of the rectangle representing the substrate 50. With this embodiment it is possible to provide an OPV device with a higher voltage without requiring very long series connection of large area solar cells. This embodiment further has the advantage that each string can be made sufficiently narrow, and cut out of the circuit in case of a defect, by sectioning at least one of the first or second conductive layers. Another advantage is, for a web production (e.g. roll-to-roll) the roll can be cut at any desired length to provide OPV devices with differentiated lengths, while the end connections are always available. While the OPV device has an increased number of individual organic solar cells, it does not have any noticeable loss in power performance, due to the very precise sectioning and interconnection, which consumes an irrelevant area if compared to device made by the prior art methods.

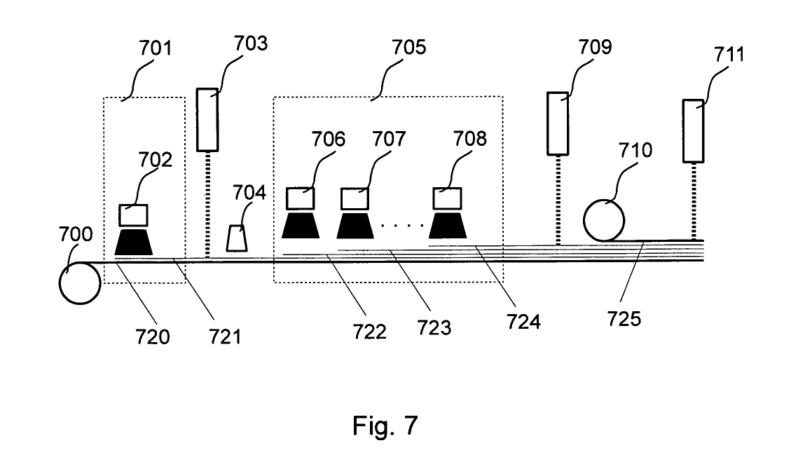

FIG. 7 shows one preferred embodiment for the fabrication of the OPV device on a web substrate 720. The web substrate 720 is fed from a roll 700, into a deposition tool 701 for deposition of the first conductive layer 721. After the deposition of the first conductive layer 721 on the web substrate 720, the first conductive layer 721 is sectioned by a means 703 which is preferably a laser. The first conductive layer 721 can be patterned into complex patterns by means 721, because the laser allows it to be made in very simple manner. After the sectioning step by means 703, the substrate and first conductive layer 721 are cleaned any means 704. The sectioning with the means 703 and cleaning 704 is preferably done outside of the deposition tool 701, and outside of the deposition tool 705. Alternatively the roll 700 already comprises a substrate 720 with a sectioned first conductive layer 721.

Still on FIG. 7, the web substrate is fed into a deposition tool 705, which is preferably a vacuum tool for deposition of layer via VTE, in which tool 705 the organic photovoltaic layers are deposited. The tool 705 comprises several sources 706, 707, . . . for deposition of the organic photovoltaic layers 722, 723, . . . . The second conductive layer 724 is deposited after the deposition of the organic photovoltaic layers 722, 723, . . . by a source 708 which may be in the same tool 705 or in a separated tool. The second conductive layer 724 is sectioned by a laser 709, after the deposition of the second conductive layer 724, which sectioning is preferably made outside the of the deposition tool 705, and preferably in an inert atmosphere (not shown). The OPV device is encapsulated with an encapsulation 725 which can be, for example, a foil from a roll 710 laminated on the device; the encapsulation is done after the sectioning of the second conductive layer 724. The electrical interconnection is provided on the OPV device with a laser 711 after the encapsulation.

The deposition tools 701 and 705 could be integral part of the same deposition tool. Also the cleaning step 704 can take place inside the tool, for instance also in low or high vacuum.

The cleaning means 704 can be, for example, plasma etching, mechanical, chemical or chemical-mechanical polishing, brushing or other equivalent means.

Following additional information on terms used is provided.

A substrate can be a rigid or flexible substrate; it can be preferentially a metal layer, a glass plate, a polymer foil, paper, or a web of one of these materials or their combinations.

A web substrate has the common technical meaning, examples of such substrates are such as a continuous sheet of paper, metal, or polymer.

Encapsulation, the encapsulation is a moisture and oxygen barrier layer, non-limiting examples are glass cover, metal cover, thin oxide or nitride films, thin film encapsulation with multilayer stack, laminated foils, edge glued foils, a combination of these, etc.

Organic photovoltaic (OPV) device is an electrical device capable of transforming light into electricity. An OPV device is comprised of at least one organic solar cell, preferably several organic solar cells. An individual organic solar cell, or simply an organic solar cell, is a single device (typically a diode) comprising two electrodes and an organic photovoltaic layer.

Section herein means to divide; to section a layer into a sections, means to pattern the layer in such a way that electrically disconnected sections (or areas) are formed.

Organic photovoltaic layer is an organic semiconductive layer used for a solar cell as known in the prior art, it comprises at least a donor-acceptor heterojunction, where at least one of the donor or acceptor materials is the light absorbing material. The organic photovoltaic layer can further comprise other layers with functions such as transport, injection, connecting units.

Interconnection or electrical interconnection are used as synonyms. The interconnection provided by a laser is an electrical connection between two electrical conductive layers made with laser through an organic photovoltaic layer. The interconnection is made after the deposition of the two electrical conductive layers and the organic photovoltaic layer, where the laser treatment promotes a local, low resistance, electrical contact between the two electrical conductive layers. Since a carbonization of the organic material is not expected, it is believed that the interconnection is a direct connection of both layers, created by locally disrupting the organic semiconductor layer. Interconnection in series or electrical interconnection in series is one kind of electrical interconnection.

Maskless (or essentially maskless): in this method the deposition area is defined by a shadow mask which defines only the limiting external borders of the layer, the shadow mask has an opening (a through-hole) which is defined by one close geometric shape, which can be convex or concave, preferentially convex, more preferentially a rectangular, closed conic section, or other closed curved shape. A non limiting example is a rectangular frame with one rectangular opening, the one rectangular opening defines the deposition area over the whole substrate, except for the borders, which need to be isolated, there is no further structure. In a continuous production process, such as a roll-to-roll process, the outer limitation of the layers can be defined by avoiding deposition at the lateral areas of the roll (or web), defining something like a margin.

### EXAMPLE

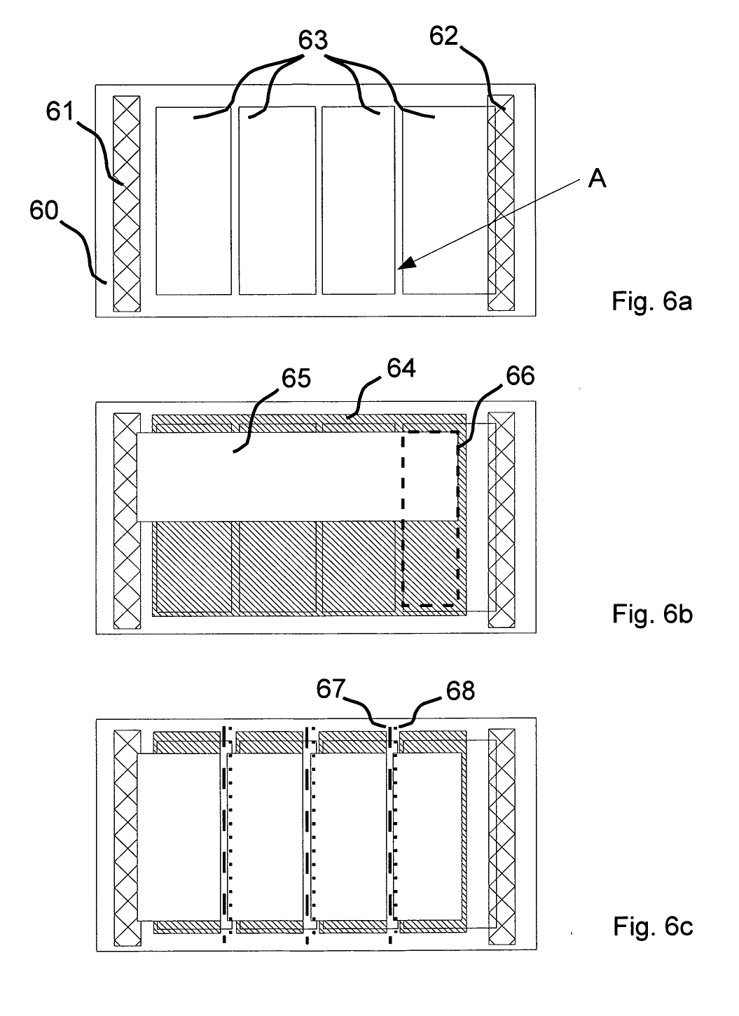

The following example will be explained in conjunction with FIG. 6a-c. An OPV device was made on a glass substrate (60), the glass substrate (60) as provided with two conductive areas (61,62) for external electrical connections. On the substrate (60), a first conductive layer was provided, this layer was made by reactive sputtering a 90 nm thick layer of indium-tin-oxide (ITO), which first conductive layer was sectioned (patterned) with laser forming the 4 rectangular sections (63). Region A indicates one region were the layer was sectioned. One of this sections (most right in FIG. 6a) overlaps with the external electrical connection layer (62). The laser used in the sectioning step was a pulsed Nd:YAG laser operating at 1064 nm configured at 400 mW, 10 ms dwell-time, pulse duration of 8 ps. The substrate was moved into high vacuum, where the organic photovoltaic layer, represented by the dashed area (64), was deposited with the following layers:
5 nm of fullerene C₆₀;
20 nm of a bulk heterojunction comprising C₆₀:ZnPc (molar ratio 2:1), were ZnPc is zinc phthalocyanine;
5 nm N,N′-diphenyl-N,N′-bis(4′-(N,N-bis(naphtha-1-yl)amino)-biphenyl-4-yl)-benzidine (DiNPB)
50 nm of DiNPB doped with 2,2′-(perfluoronaphthalene-2,6-diylidene)dimalononitrile (2 mol %);
10 nm of ZnPc doped with 2,2′-(perfluoronaphthalene-2,6-diylidene)dimalononitrile (4 mol %);

The second conductive layer, a 100 nm thick Au:Ag (atomic ratio 1:1) layer, represented by the rectangle (65), was deposited on top of the organic photovoltaic layer. Only the upper half of the second conductive layer (65) is shown, to explicitly show that the organic photovoltaic layer is unpatterned. The second conductive layer is also unpatterned, at this stage. The substrate was taken out of the vacuum chamber and stored in a glove box filled with nitrogen.

In the glovebox, after the providing the layers 64 and 65, a glass encapsulation is provided, by gluing a glass cover to the substrate using a light curing sealant XNR5516 (Nagase). The glass cover contained moisture and oxygen getter adhesives in its interior. Thin film encapsulation, such as a multilayer barrier could have been provided instead of a glass cover.

The OPV device was almost completed, still requiring the serial connection. For that purpose, the substrate was taken out of the glove box and the interconnection between the first and second conductive layers and the sectioning of the second conductive layers were performed. Although the order of the steps of interconnection and sectioning are not relevant, the following procedure was performed for the purpose of measuring the quality of the connections:

At this stage, the external electrical connections (61, 62) can be used to measure the quality of the sectioning and of the interconnection. An open circuit voltage of 0.55 V was measured at the external electrical connections (61, 62), the active solar cell is defined by the area 66. After sectioning the second conductive layer (63) by laser ablating a line (FIG. 6c, dashed line 67), the measured resistance (both polarities, bias=1 V), was indicated as infinity (open circuit), proving that the layer 63 was successfully sectioned into two sections. The laser used in the sectioning step was a pulsed Nd:YAG laser operating at 1064 nm configured at 400 mW, 10 ms dwell-time, pulse duration of 8 ps. The interconnection was performed at the dotted line (68), making a series connection of the two most left solar cells. After the interconnection step, an open circuit voltage of 1.1 V was measured at the external electrical connections (61, 62). The laser used in the sectioning step was a pulsed Nd:YAG laser operating at 1064 nm configured at 400 mW, 10 ms dwell-time, pulse duration of 8 ps, the laser was firstly calibrated by measuring the resistance between two conductive layers, before and after an interconnection, in calibration samples with made was the same layer stack configuration as the OPV device. The calibration could also have been performed on the OPV device directly, or the calibration data could be pre-programmed in the equipment comprising the laser. After finishing all sectioning steps (FIG. 6c, dashed lines) and all interconnections (FIG. 6c, dotted lines), an open circuit voltage of 2.2 V was measured.

Other lasers were also tested, and the parameters for each different laser can be easily adjusted to provide the interconnection.

The features disclosed in at least one of the specification, the claims, and the figures may be material for the realization of the invention in its various embodiments, taken in isolation or in various combinations thereof.

1. A method for forming an electrical interconnection in an organic photovoltaic device, the method comprising steps of:
providing a first conductive layer,
providing an organic photovoltaic layer, over the first conductive layer,
providing a second conductive layer, over the organic photovoltaic layer,
providing an encapsulation, and
providing an electrical interconnection between the first conductive layer and the second conductive layer.

2. Method according to claim 1, wherein the step of providing an interconnection is performed by laser.

3. Method according to claim 1, wherein the step of providing the interconnection comprises providing several aligned interconnections.

4. (canceled)

5. Method according to claim 1, wherein at least one of the organic photovoltaic layer and the second conductive layer, are formed on the substrate by a maskless deposition process comprising a step of maskless depositing materials in at least an active area.

6. Method according to claim 1, wherein the first conductive layer is provided with a first and a second section.

7. Method according to claim 6, wherein, before the step of providing an organic photovoltaic layer, the first conductive layer is sectioned into a first and a second section.

8. Method according to claim 6, wherein the step of providing an interconnection consists of:
providing an electrical interconnection between the first section of the first conductive layer and the second section of the second conductive layer,
sectioning the second conductive layer into a first section and a second section, wherein the first section of the second conductive layer is electrically short disconnected to the first section of the first conductive layer and is electrically short connected to the second section of the first conductive layer.

9. Method according to claim 6, wherein the step of providing an interconnection consists of:
sectioning the second conductive layer into a first section and a second section,
electrically interconnecting the first section of the first conductive layer with the second section of the second conductive layer.

10. Organic photovoltaic device made by a method according to claim 1, comprising a substrate, a first string, the first string comprising in series connected organic solar cells over the substrate, wherein the series connection comprises electrical interconnections between the first conductive layer and the second conductive layer, wherein the device is a large area device.

11. Organic photovoltaic device according to claim 10, wherein the first string comprises electrical terminals at its ends.

12. Organic photovoltaic device according to claim 10, comprising a second string electrically connected in parallel to the first string.

13. Use of an organic photovoltaic device according to claim 10 in a window for an edification.
